(19) United States
(12) Patent Application Publication
(10) Pub. No.: US 2022/0363546 A1
(43) Pub. Date: Nov. 17, 2022

(54) GRAPHENE COMPOSITE AND METHOD FOR MANUFACTURING THE SAME

(71) Applicant: University Of Seoul Industry Cooperation Foundation, Seoul (KR)

(72) Inventors: Young Jun Chang, Seoul (KR); Byoung Ki Choi, Yongin-si (KR)

(21) Appl. No.: 17/721,475

(22) Filed: Apr. 15, 2022

(30) Foreign Application Priority Data
May 12, 2021 (KR) 10-2021-0061607

(51) Int. Cl. C01B 32/194; C30B 29/46; C30B 23/02

(52) U.S. Cl. CPC C01B 32/194; C30B 29/46; C30B 23/025

(57) ABSTRACT

The present disclosure relates to a graphene composite and a method of manufacturing the same, and a graphene composite according to an exemplary embodiment includes: a substrate; a first thin film positioned on the substrate; and a second thin film positioned on the first thin film, in which the first thin film includes graphene, and the second thin film includes at least any one of VSe₂, VS₂, VTe₂, TaS₂, TaSe₂, NbS₂, NbSe₂, TiS₂, TiSe₂, TiTe₂, ReS₂, and ReSe₂.

### CROSS-REFERENCE TO RELATED APPLICATION

This application claims priority to and the benefit of Korean Patent Application No. 10-2021-0061607 filed in the Korean Intellectual Property Office on May 12, 2021, the entire contents of which are incorporated herein by reference.

### BACKGROUND OF THE INVENTION

### (a) Field of the Invention

The present disclosure relates to a grapheme composite and a method of manufacturing the same.

### (b) Description of the Related Art

Graphene is a type of carbon allotrope, and carbon atoms exist at the vertices of a hexagon and form a two-dimensional planar crystal structure in the shape of a widely spread hexagonal honeycomb. Graphene is a film having a thickness of one atom and exists in a stable structure. The thickness of graphene is about 0.2 nm, but has high physical and chemical stability.

Graphene is an ultra-thin film material that is 100 times stronger than steel and can conduct heat and electricity. Thus, graphene has the potential to make electronics faster than silicon electronics. However, for this to be possible, graphene must be able to turn on/off current. That is, graphene needs to have a bandgap.

Graphene does not have a bandgap, and various studies have been made to create a bandgap of graphene, but there is a problem that it is not easy to synthesize graphene having a bandgap.

The above information disclosed in this Background section is only for enhancement of understanding of the background of the invention, and therefore it may contain information that does not form the prior art that is already known in this country to a person of ordinary skill in the art.

### SUMMARY OF THE INVENTION

The present invention has been made in an effort to provide a graphene composite applicable to a graphene-based semiconductor device by adjusting a band gap of graphene according to a temperature, and a method of manufacturing the same.

The present invention has also been made in an effort to provide a graphene composite which is producible with a large area with a short process time at a low temperature and is applicable onto various substrates, and a method of manufacturing the same.

An exemplary embodiment of the present invention provides a graphene composite including: a substrate; a first thin film positioned on the substrate; and a second thin film positioned on the first thin film, in which the first thin film includes graphene, and the second thin film includes at least any one of VSe₂, VS₂, VTe₂, TaS₂, TaSe₂, NbS₂, NbSe₂, TiS₂, TiSe₂, TiTe₂, ReS₂, and ReSe₂.

The second thin film may be in contact with the first thin film.

The first thin film may be formed as a graphene single layer or graphene multi-layers.

Another exemplary embodiment of the present invention provides a graphene composite including: a substrate; a first thin film which is positioned on the substrate and includes graphene; and a second thin film which is positioned on the first thin film and includes a material having a periodic pattern changed according to a temperature.

The first thin film may have an insulating property at a temperature lower than a phase transition temperature and have conductivity at a temperature higher than the phase transition temperature.

The second thin film may include VSe₂, and the first thin film may have conductivity at a temperature higher than −140° C.

The second thin film may include at least one of VSe₂, VS₂, VTe₂, TaS₂, TaSe₂, NbS₂, NbSe₂, TiS₂, TiSe₂, TiTe₂, ReS₂, and ReSe₂.

Still another exemplary embodiment of the present invention provides a method of manufacturing a graphene composite, the method including: forming a first thin film including graphene on a substrate; and forming a second thin film on the first thin film, in which the second thin film includes at least one of VSe₂, VS₂, VTe₂, TaS₂, TaSe₂, NbS₂, NbSe₂, TiS₂, TiSe₂, TiTe₂, ReS₂, and ReSe₂.

The forming of the second thin film may use a molecular beam epitaxy method.

The forming of the second thin film may include depositing V and Se on the first thin film at the same time.

According to the exemplary embodiments, the bandgap of the graphene is adjustable according to a temperature, so that the graphene composite is applicable to graphene-based semiconductor devices, sensor devices, and infrared-terawave sensor devices.

Further, the graphene composite is producible with a large area with a short process time at a low temperature and is applicable onto various substrates, thereby improving production efficiency.

### BRIEF DESCRIPTION OF THE DRAWINGS

FIG. 1 is a cross-sectional view illustrating a graphene composite according to an exemplary embodiment.

FIG. 2 is a diagram illustrating a change in a characteristic of the graphene composite according to a temperature according to the exemplary embodiment.

FIG. 3 is a diagram illustrating a change in a potential and a band structure of the graphene composite according to a temperature according to the exemplary embodiment.

FIG. 4 is a diagram illustrating a change in a characteristic and a band structure of the graphene composite according to a temperature according to the exemplary embodiment.

FIG. 5 is a graph illustrating a structure of a Dirac band of graphene according to the reference example, and a structure of a Dirac band of the graphene composite according to the exemplary embodiment.

FIG. 6 is a graph illustrating a size of a bandgap according to a temperature of the graphene composite according to the exemplary embodiment.

FIG. 7 is a diagram illustrating the structure of the Dirac band of graphene according to the reference example, and a structure of the Dirac band of the graphene composite according to the exemplary embodiment.

FIG. 8 is a graph illustrating a size of a bandgap according to a temperature of the graphene composite according to the exemplary embodiment.

FIG. 9 and FIG. 10 are diagrams illustrating various patterns of a second thin film of the graphene composite according to the exemplary embodiment.

FIG. 11 and FIG. 12 are process cross-sectional views sequentially illustrating a method of manufacturing the graphene composite according to an exemplary embodiment.

### DETAILED DESCRIPTION OF THE EMBODIMENTS

In the following detailed description, only certain exemplary embodiments of the present invention have been shown and described, simply by way of illustration. However, the present invention can be variously implemented and is not limited to the following embodiments.

Accordingly, the drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto. In the drawings, the thickness of layers, films, panels, regions, etc., are exaggerated for clarity. In the drawings, for understanding and ease of description, the thickness of some layers and areas is exaggerated.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

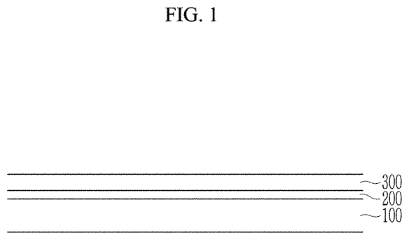

First, a graphene complex according to an exemplary embodiment will be described below with reference to FIG. 1.

FIG. 1 is a cross-sectional view illustrating a graphene composite according to an exemplary embodiment.

As illustrated in FIG. 1, a graphene composite according to the exemplary embodiment includes a substrate 100, a first thin film 200, and a second thin film 300.

The substrate 100 may be formed of, for example, an SiC substrate. However, the material of the substrate 100 is not limited thereto, and may be variously changed. Further, the substrate 100 may be made of a flexible material, and the graphene composite according to the exemplary embodiment may also be used in a flexible element.

The first thin film 200 may be positioned on the substrate 100. The first thin film 200 may include graphene. Graphene, as one of the carbon allotropes, is thin, light and highly durable, has high malleability, electron mobility, high thermal conductivity, and large Young's coefficient, and has a large theoretical specific surface area. In addition, graphene may be formed as a single layer, so that the amount of absorption for visible light is small, and the transmittance at 550 nm is 97.7%, and graphene may be used in a transparent-flexible electronic device. The first thin film 200 may be formed as a graphene single layer, but is not limited thereto. The first thin film 200 may be formed as graphene multiple layers, such as graphene dual layers.

The second thin film 300 may be positioned on the first thin film 200. Therefore, the first thin film 200 is positioned between the substrate 100 and the second thin film 300. The second thin film 300 may be positioned directly on the first thin film 200. Therefore, the second thin film 300 may be in contact with the first thin film 200. The second thin film 300 may include at least one of VSe₂, VS₂, VTe₂, TaS₂, TaSe₂, NbS₂, NbSe₂, TiS₂, TiSe₂, TiTe₂, ReS₂, and ReSe₂. However, the material of the second thin film 300 is not limited thereto, and may be variously changed. The second thin film 300 may be made of a material having a periodic pattern changed according to a temperature. In addition to the foregoing material examples, the second thin film 300 may be made of various materials having periodic patterns changed according to a temperature.

In general, graphene does not have a bandgap. The graphene composite according to the exemplary embodiment may have a bandgap within a predetermined temperature range by forming the second thin film 300 made of the material, such as VSe₂, VS₂, VTe₂, TaS₂, TaSe₂, NbS₂, NbSe₂, TiS₂, TiSe₂, TiTe₂, ReS₂, and ReSe₂, on the first thin film 200 formed of graphene.

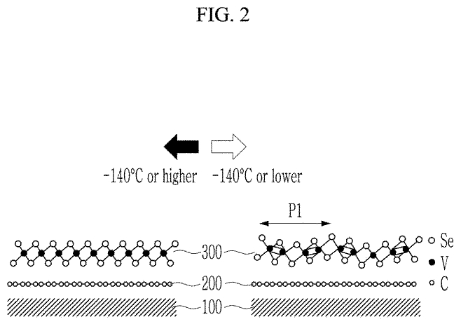

Hereinafter, a principle in which the graphene composite according to the exemplary embodiment has a bandgap will be described with reference to FIGS. 2 to 4.

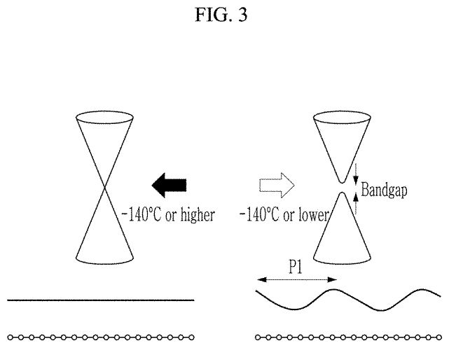

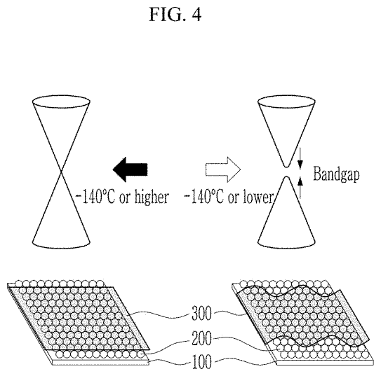

FIG. 2 is a diagram illustrating a change in a characteristic of the graphene composite according to a temperature according to the exemplary embodiment, FIG. 3 is a diagram illustrating a change in a potential and a band structure of the graphene composite according to a temperature according to the exemplary embodiment, and FIG. 4 is a diagram illustrating a change in a characteristic and a band structure of the graphene composite according to a temperature according to the exemplary embodiment.

As illustrated in FIG. 2, a characteristic of the graphene composite according to the exemplary embodiment may be changed based on a predetermined temperature. For example, in the graphene composite according to the exemplary embodiment, the first thin film 200 may be formed as a graphene single layer, and the second thin film 300 may be made of VSe₂. In this case, the arrangement of V atoms and Se atoms constituting the second thin film 300 may be different depending on the temperature. For example, the distance between V and Se constituting the second thin film 300 at a temperature higher than −140° C. may be constant, and the distance between V and Se constituting the second thin film 300 at a temperature lower than −140° C. may be decreased in some regions. In this case, V and Se constituting the second thin film 300 at the temperature lower than −140° C. may form a predetermined repeated pattern. That is, the second thin film 300 may include a material having a periodic pattern changed according to a temperature. As shown in FIG. 3, the periodicity of the potential may be induced according to a period P1 of the pattern formed on the second thin film 300.

In addition, investigating the band structure of the graphene composite according to the exemplary embodiment at the temperature higher than −140° C., it can be confirmed that there is no bandgap. Therefore, the graphene composite according to the exemplary embodiment has conductivity at the temperature higher than −140° C. On the other hand, investigating the band structure of the graphene composite according to the exemplary embodiment at the temperature lower than −140° C., it can be confirmed that there is the bandgap. Therefore, the graphene composite according to the exemplary embodiment has insulating properties at the temperature lower than −140° C. As described above, the graphene composite according to the exemplary embodiment may have the insulating property or the conductive property according to a temperature. The temperature at the point where this characteristic conversion occurs is called a phase transition temperature. When the second thin film 300 of the graphene composite according to the exemplary embodiment is made of VSe₂, the phase transition temperature at which the state of the graphene composite is changed from the conductive state to the insulating state may be about −140° C. When the material constituting the second thin film 300 is changed, the phase transition temperature may also be changed.

As illustrated in FIG. 4, the bandgap characteristic of the graphene composite according to the exemplary embodiment may be related to the characteristic that the material constituting the second thin film 300 has the periodic pattern changed according to the temperature. That is, the material constituting the second thin film 300 of the graphene composite according to the exemplary embodiment has the periodic pattern at the temperature lower than the phase transition temperature, and thus, wrinkles are generated, so that the graphene composite according to the exemplary embodiment may have the bandgap. Conversely, the wrinkles of the material constituting the second thin film 300 of the graphene composite according to the exemplary embodiment are stretched at the temperature higher than the phase transition temperature, and the band gap of the graphene composite according to the exemplary embodiment disappears.

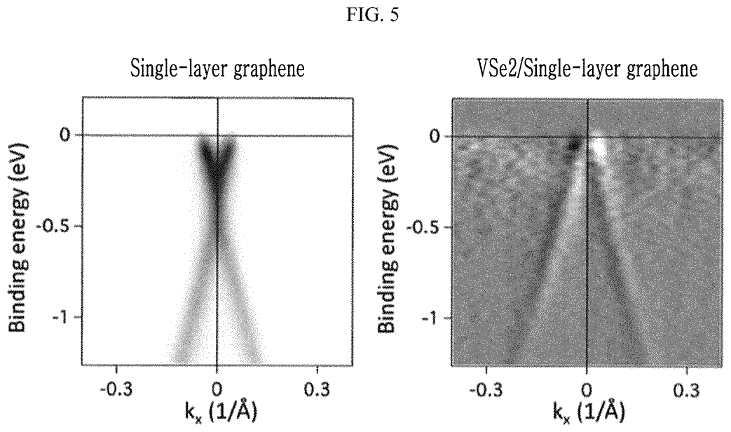

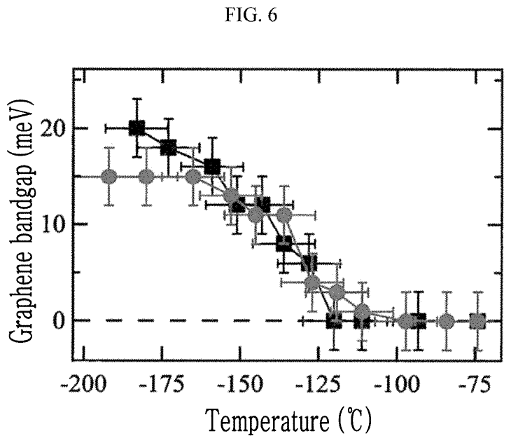

Hereinafter, the bandgap characteristic in the case where the first thin film of the graphene composite according to the exemplary embodiment is formed as a graphene single layer will be described through the comparison with the graphene of the Reference Example with reference to FIGS. 5 and 6.

FIG. 5 is a graph illustrating a structure of a Dirac band of graphene according to the reference example, and a structure of a Dirac band of the graphene composite according to the exemplary embodiment, and FIG. 6 is a graph illustrating a size of a bandgap according to a temperature of the graphene composite according to the exemplary embodiment. FIGS. 5 and 6 illustrate the case where the first thin film of the graphene composite according to the exemplary embodiment is formed as a graphene single layer.

The graphene according to the reference example does not include the second thin film unlike the graphene composite according to the exemplary embodiment. As illustrated in FIG. 5, the graphene according to the reference example having a structure in which a graphene single layer is positioned on an SiC substrate shows an n-type doped Dirac band structure. The graphene composite according to the exemplary embodiment in which the first thin film formed as the graphene single layer is positioned on the SiC substrate and the second thin film made of VSe₂ is positioned on the first thin film shows a band structure in a neutral state that is p-type doped.

As illustrated in FIG. 6, in the case of the graphene composite according to the exemplary embodiment, it can be confirmed that the bandgap is maintained at 0 at the temperature about −140° C. or higher, and the bandgap is rapidly opened at the temperature of about −140° C. or lower. At the temperature of about −140° C. or less, the bandgap of the graphene composite according to the exemplary embodiment may increase from about 15 meV to about 20 meV.

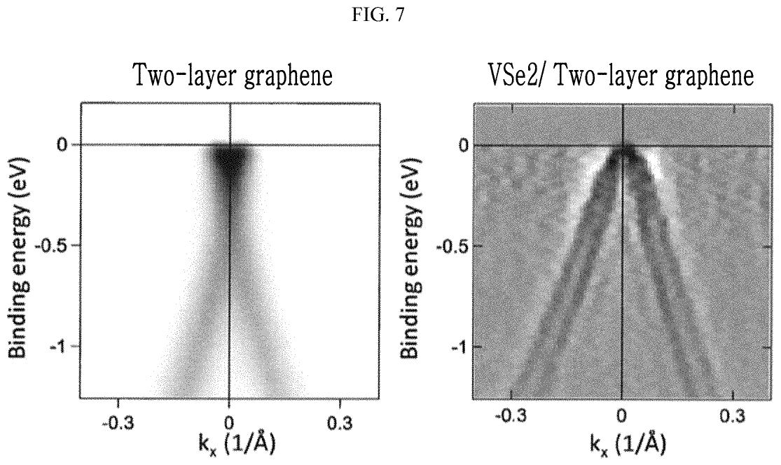

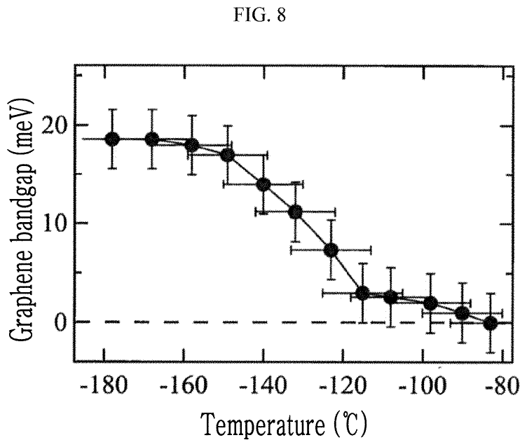

Hereinafter, the bandgap characteristic in the case where the first thin film of the graphene composite according to the exemplary embodiment is formed as graphene dual layers will be described through the comparison with the graphene of the Reference Example with reference to FIGS. 7 and 8.

FIG. 7 is a diagram illustrating the structure of the Dirac band of graphene according to the reference example, and a structure of the Dirac band of the graphene composite according to the exemplary embodiment, and FIG. 8 is a graph illustrating a size of a bandgap according to a temperature of the graphene composite according to the exemplary embodiment. FIGS. 7 and 8 illustrate the case where the first thin film of the graphene composite according to the exemplary embodiment is formed as graphene dual layers.

The graphene according to the reference example does not include the second thin film unlike the graphene composite according to the exemplary embodiment. As illustrated in FIG. 7, the graphene according to the reference example having a structure in which graphene dual layers are positioned on an SiC substrate shows an n-type doped Dirac band structure. The graphene composite according to the exemplary embodiment in which the first thin film formed as the graphene dual layers is positioned on the SiC substrate and the second thin film made of VSe₂ is positioned on the first thin film shows a band structure in a neutral state that is p-type doped.

As illustrated in FIG. 6, in the case of the graphene composite according to the exemplary embodiment, it can be confirmed that the bandgap is maintained at 0 at the temperature about −140° C. or higher, and the bandgap is rapidly opened at the temperature of about −140° C. or lower. At the temperature of about −140° C. or less, the bandgap of the graphene composite according to the exemplary embodiment may increase to about 19 meV.

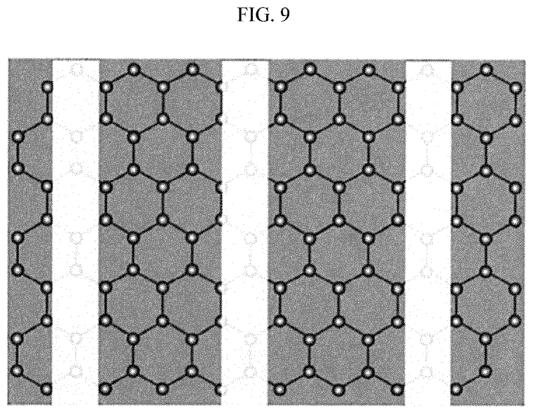

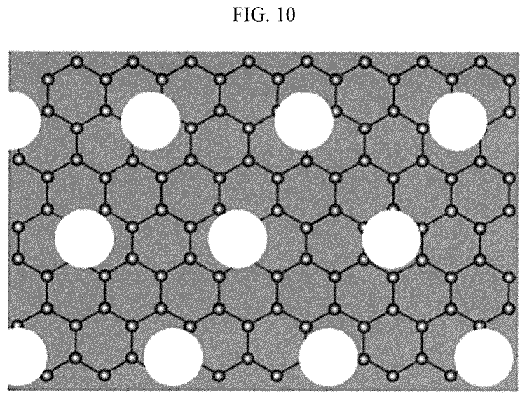

Hereinafter, a pattern characteristic of the second thin film of the graphene composite according to the exemplary embodiment will be described with reference to FIGS. 9 and 10.

FIG. 9 and FIG. 10 are diagrams illustrating various patterns of the second thin film of the graphene composite according to the exemplary embodiment.

As illustrated in FIG. 9 and FIG. 10, the second thin film of the graphene composite according to the exemplary embodiment may have a periodic pattern in the atom level. For example, as illustrated in FIG. 9, the second thin film of the graphene composite according to the exemplary embodiment may have a periodic linear pattern. As illustrated in FIG. 10, the second thin film of the graphene composite according to the exemplary embodiment may have a form in which a periodic circular pattern is placed at each corner of a triangle. In the second thin film of the graphene composite according to the exemplary embodiment, the periodic patterns may appear and disappear according to the change in the temperature. The form and the period of the pattern may be varied according to the material constituting the second thin film. For example, when the second thin film of the graphene composite according to the exemplary embodiment is made of VSe₂, a linear pattern having a period of about 1 nm may be exhibited. When the second thin film of the graphene composite according to the exemplary embodiment is made of TaS₂, the second thin film may have has a period of about 1.3 nm, and exhibit a form in which a circular pattern and is disposed at each corner of the triangle. When the second thin film of the graphene composite according to the exemplary embodiment is made of TaSe₂, the second thin film may have a period of about 1 nm and exhibit a form in which a circular pattern is disposed at each corner of the triangle. When the second thin film of the graphene composite according to the exemplary embodiment is made of NbSe₂, the second thin film may have a period of about 1 nm and exhibit a form in which a circular pattern is disposed at each corner of the triangle, and exhibit a linear pattern having a period of about 0.9 nm. When the second thin film of the graphene composite according to the exemplary embodiment is made of TiSe₂ or TiTe₂, the second thin film may have a period of about 0.7 nm and exhibit a form in which a circular pattern and is disposed at each corner of the triangle.

The second thin film of the graphene composite according to the exemplary embodiment may also be made of other materials, in addition to the foregoing materials, and thus the shape and the period of the pattern of the second thin film may also be variously changed.

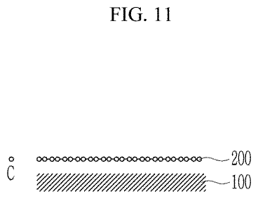

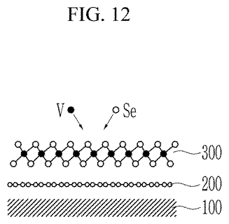

Hereinafter, a method of manufacturing the graphene composite according to an exemplary embodiment will be described below with reference to FIGS. 11 and 12.

FIG. 11 and FIG. 12 are process cross-sectional views sequentially illustrating a method of manufacturing the graphene composite according to an exemplary embodiment.

First, as illustrated in FIG. 11, a first thin film 200 including graphene is formed on a substrate 100. The first thin film 200 may be formed as a graphene single layer. However, the first thin film 200 is not limited thereto, and the first thin film 200 may also be formed as graphene multi layers, such as graphene dual layers.

As illustrated in FIG. 12, a second thin film 300 is formed by depositing V and Se on the first thin film 200 at the same time. In this case, the operation of forming the second thin film 300 may use Molecular Beam Epitaxy (MBE). The second thin film 300 may be formed by performing a deposition process at a temperature of about 300° C. The second thin film 300 may be formed at a relatively low temperature in a short process time of about 1 hour, and may be formed in a single manufacturing process. In addition, the second thin film 300 may be grown in a large area, and may be applied to graphene mounted on various substrates.

Since this second thin film may be stacked to a very thin thickness of about 0.61 nm, transparency and flexibility of the graphene composite according to the exemplary embodiment may maintained. Therefore, the graphene composite according to the exemplary embodiment is applicable to a transparent electronic device, a flexible electronic device, and the like. Further, the graphene composite according to the exemplary embodiment may be formed with the small thickness and the bandgap of the graphene is adjustable according to a temperature, so that the graphene composite according to the exemplary embodiment is applicable to various electronic devices sensitive to a temperature and an infrared signal. For example, the graphene composite according to the exemplary embodiment is applicable to graphene-based semiconductor devices, sensor devices, and infrared-terawave sensor devices.

In the above, the second thin film 300 has been described as being formed by depositing V and Se at the same time and in this case, the second thin film 300 may be made of VSe₂. However, the second thin film 300 is not limited thereto, and the second thin film 300 may be formed of other materials. For example, the second thin film 300 made of TaSe₂ may be formed by depositing Ta and Se at the same time by using the MBE. In addition, the second thin film 300 may include at least one among various materials, such as VS₂, VTe₂, TaS₂, NbS₂, NbSe₂, TiS₂, TiSe₂, TiTe₂, ReS₂, and ReSe₂. The second thin film 300 may be made of a material having a periodic pattern changed according to a temperature.

Although an exemplary embodiment of the present invention has been described in detail, the scope of the present invention is not limited by the embodiment. Various changes and modifications using the basic concept of the present invention defined in the accompanying claims by those skilled in the art shall be construed to belong to the scope of the present invention.

### DESCRIPTION OF SYMBOLS

100: Substrate
200: First thin film
300: Second thin film

What is claimed is:

1. A graphene composite comprising:
a substrate;
a first thin film positioned on the substrate; and
a second thin film positioned on the first thin film,
wherein the first thin film includes graphene, and
the second thin film includes at least any one of VSe₂, VS₂, VTe₂, TaS₂, TaSe₂, NbS₂, NbSe₂, TiS₂, TiSe₂, TiTe₂, ReS₂, and ReSe₂.

2. The graphene composite of claim 1, wherein:
the second thin film is in contact with the first thin film

3. The graphene composite of claim 1, wherein:
the first thin film is formed as a graphene single layer or graphene multi-layers.

4. A graphene composite comprising:
a substrate;
a first thin film which is positioned on the substrate and includes graphene; and
a second thin film which is positioned on the first thin film and includes a material having a periodic pattern changed according to a temperature.

5. The graphene composite of claim 4, wherein:
the first thin film has an insulating property at a temperature lower than a phase transition temperature and has conductivity at a temperature higher than the phase transition temperature.

6. The graphene composite of claim 4, wherein:
the second thin film includes VSe₂, and the first thin film has conductivity at a temperature higher than −140° C.

7. The graphene composite of claim 4, wherein:
the second thin film includes at least one of VSe₂, VS₂, VTe₂, TaS₂, TaSe₂, NbS₂, NbSe₂, TiS₂, TiSe₂, TiTe₂, ReS₂, and ReSe₂.

8. A method of manufacturing a graphene composite, the method comprising:
forming a first thin film including graphene on a substrate; and
forming a second thin film on the first thin film,
wherein the second thin film includes at least one of VSe₂, VS₂, VTe₂, TaS₂, TaSe₂, NbS₂, NbSe₂, TiS₂, TiSe₂, TiTe₂, ReS₂, and ReSe₂.

9. The method of claim 8, wherein:
the forming of the second thin film uses a molecular beam epitaxy method.

10. The method of claim 9, wherein:
the forming of the second thin film includes depositing V and Se on the first thin film at the same time.
